(19) United States
(12) Patent Application Publication
(10) Pub. No.: US 2007/0074898 A1
(43) Pub. Date: Apr. 5, 2007

(54) Pads for printed circuit board

(75) Inventors: Chan-Fei Tai, Tu-Cheng (TW); Ya-Ling Huang, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/490,400

(22) Filed: Jul. 20, 2006

(30) Foreign Application Priority Data
Sep. 30, 2005 (CN) 200510100109.3

(51) Int. Cl. H05K 1/16

(52) U.S. Cl. 174/260

(57) ABSTRACT

A pad is adapted for selectively receiving a first surface mounted component (SMC) and a second SMC on a printed circuit board. The first SMC and the second SMC include a number of footprints respectively. The pad includes a first portion for receiving the first SMC, a second portion for receiving the second SMC. Configurations and sizes of the first portion and the second portion are same with the ones of the footprints of the first SMC and the second SMC respectively. The second portion is overlapped with the first portion. The pad can selectively receive one of the first SMC and the second SMC.

### BACKGROUND

1. Field of the Invention

The present invention relates to pads for a printed circuit board (PCB), and more particularly to a pad which is capable of receiving one of a variety of surface mounted components (SMCs).

2. General Background

In general, SMCs, including resistors, capacitors, inductances and so on, are connected to a printed circuit board by pads. The pads are arranged on the printed circuit board in a matched relationship with footprints of the SMCs. The pads have different configurations due to varied configurations of the footprints of the SMCs, such as a circle, a square, a teardrop, and so on. However, the pad generally is only capable of receiving a certain SMC.

Referring to FIG. 3, a printed circuit board 100′ includes a number of SMCs, such as a 0805-type resistor 11, a 0603-type resistor 21, and a common-chock inductance 31. A pair of pads 10′ is formed on the PCB 100′ for receiving the 0805-type resistor 11, a pair of pads 20′ is formed on the PCB 100′ for receiving the 0603-type resistor 21, and two pairs of pads 30′ are formed on the PCB 100′ for receiving the common-chock inductance 31. The 0805-type resistor 11 and the 0603-type resistor 21 have two footprints respectively, and the common-chock inductance 31 has four footprints. The number and configuration of footprints of the 0805-types resistor 11, the 0603-type resistor 21, and the common-chock inductance 31 are different. Therefore, each of theses different SMCs require a different corresponding pad. However, room on the printed circuit board is limited. Too many pads will decrease layout room for electronic components and traces on the PCB.

What is needed is a pad which is capable of receiving one of a variety of SMCs.

### SUMMARY

An exemplary pad is adapted for a selective receiving of a first SMC and a second SMC on a printed circuit board. The first SMC and the second SMC include a number of footprints respectively. The pad includes a first portion for receiving the first SMC, a second portion for receiving the second SMC. Configurations and sizes of the first portion and the second portion are same with the ones of the footprints of the first SMC and the second SMC respectively. The second portion is overlapped with the first portion. The pad can selectively receive one of the first SMC and the second SMC.

Other advantages and novel features will become more apparent from the following detailed description when taken in conjunction with the accompanying drawings, in which:

### BRIEF DESCRIPTION OF THE DRAWINGS

FIG. 1 is a plan view of a pad on a printed circuit board for receiving one of a 0805-type resistor and 0603-type resistor in accordance with a preferred embodiment of the present invention;

FIG. 2 is a plan view of another pad on the printed circuit board for receiving a common-chock inductance, or receiving a 0805-type resistor and a 0603-type resistor, in accordance with a preferred embodiment of the present invention; and

FIG. 3 is a plan view of conventional pads on a printed circuit board for receiving the 0805-type resistor, the 0603-type resistor, and the common-chock inductance respectively.

### DETAILED DESCRIPTION OF THE EMBODIMENTS

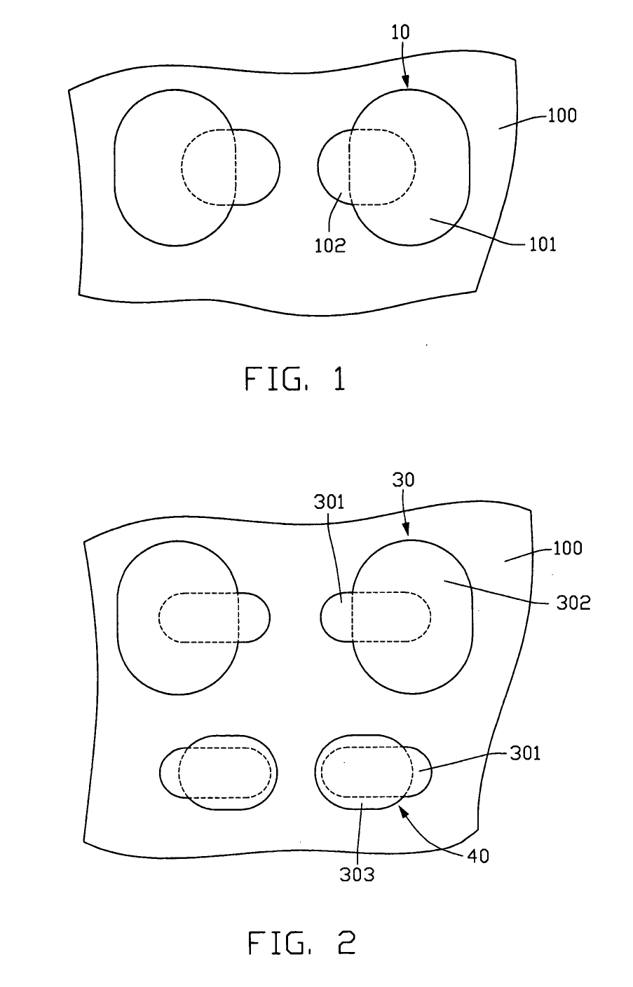

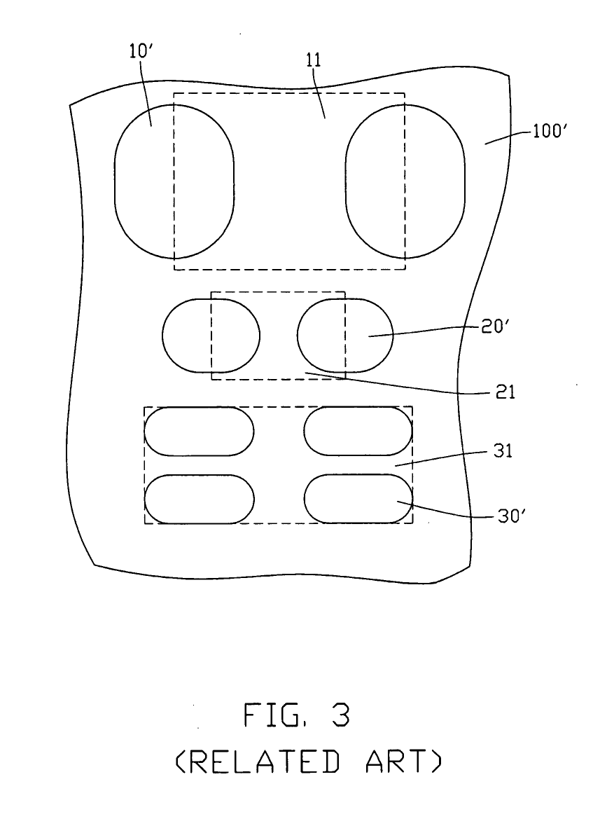

Referring to FIG. 1, a pair of pads 10 of a circuit assembly like a printed circuit board (PCB) 100 for receiving one of surface mounted components (SMCs) including a 0805-type resistor and a 0603-type resistor is shown. Each of the pads 10 includes a first portion 101 and a second portion 102. The first portion 101 is for matching with footprints of the 0805-type resistor and receiving the 0805-type resistor, and the second portion 102 is for matching with footprints of the 0603-type resistor and receiving the 0603-type resistor. The first portion 101 is overlapped with the second portion 202. A distance between the first portions 101 is same with a distance between two footprints of the 0805-type resistor. A distance between the second portions 102 is same with a distance between two footprints of the 0603-type resistor. Configurations of the first portion 101 and the second portion 102 are same with configurations of the footprints of 0805-type resistor and the 0603-type resistor respectively. Therefore, the pads 10 are advantageously configured to receive one of the 0805-type resistor and the 0603-type resistor.

Referring to FIG. 2, two pairs of pads 30 and 40 can receive a common-chock inductance with four footprints, or receive both the 0805-type resistor and the 0603-type resistor. Each of the pads 30 includes a first portion 301 and a second portion 302, and each of the pads 40 includes a third portion 303 and another of the first portion 301. The four first portions 301 are for matching with and receiving the footprints of the common-chock inductance, so configurations and sizes of the first portions 301 are same with the ones of the footprints of the common-chock inductance. The second portions 302 are for receiving the 0805-type resistor, so configurations and sizes of the second portions 302 are same with the ones of the 0805-type resistor. The third portions 303 are for receiving the 0603-type resistor, so configurations and sizes of the third portions 303 are same with the ones of the footprints of the 0603-type resistor. As for the pads 30, the first portion 301 is overlapped with the second portion 302, and as for the pads 40, the first portion 302 is overlapped with the third portion 303. Arrangement of the first portion 301, the second portion 302, and the third portion 303 is determined by a positional relationship among the footprints of the common-chock inductance, the 0805-type resistor, and the 0603-type resistor. Because the first portion 301 is overlapped with the second portion 302 and the third portion 303 respectively, the pads 30 and 40 can alternatively receive the common-chock inductance, or receive both the 0805-type resistor and the 0603-type resistor.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

What is claimed is:

1. A pad for a selectively receiving a first surface mounted component (SMC) and a second SMC on a printed circuit board (PCB), the first SMC and the second SMC each having two footprints, the pad comprising:
a first portion for receiving the first SMC, a configuration and size of the first portion being similar with each of the footprints of the first SMC; and
a second portion for receiving the second SMC, a configuration and size of the second portion being similar with the footprints of the second SMC, the second portion overlapped with the first portion.

2. The pad as claimed in claim 1, wherein the pad comprises two pads for receiving two footprints of one of the first SMC and the second SMC.

3. The pad as claimed in claim 1, wherein the first SMC and the second SMC are two resistors.

4. A printed circuit board (PCB) having a pad arrangement for selectively receiving a first surface mounted component (SMC), a second SMC, and a third SMC, the first SMC and the second SMC each having two footprints, the third SMC having four footprints, the PCB comprising:
a pair of first pads for receiving the first SMC;
a pair of second pads for receiving the second SMC; and
two pairs of third pads for receiving the third SMC, one pair of the third pads overlapped with the first pads, the other pair of the third pads overlapped with the second pads.

5. The PCB as claimed in claim 4, wherein the first SMC can be mounted on the first pads, and the second SMC can be mounted on the second pads at the same time time.

6. The PCB as claimed in claim 4, wherein arrangement of the first pads, the second pads, and the third pads is determined by a positional relationship among the footprints of the first SMC, the second SMC, and the third SMC.

7. The PCB as claimed in claim 4, wherein the first SMC and the second SMC are two resistors, and the third SMC is an inductance.

8. A circuit assembly comprising:
a first group of pad portions disposed at said circuit assembly and configured for matching with footprints of a first component to mount said first component thereon;
a second group of pad portions disposed at said circuit board assembly spaced from said first group of pad portions and configured for matching with footprints of a second component to mount said second component thereon; and
a third group of pad portions disposed at said circuit assembly and configured for matching with footprints of a third component to mount said third component thereon, at least one of said third group of pad portions overlapping with one of said first group of pad portions, and at least another one of said third group of pad portions overlapping with one of said second group of pad portions.

9. The circuit assembly as claimed in claim 8, wherein each pad portion from said third group of pad portions overlaps with one pad portion from said first and second groups of pad portions, and a total number of said third group of pad portions equals with a total number of said first and second groups of pad portions.
